(19) United States
(12) Patent Application Publication
(10) Pub. No.: US 2025/0056938 A1
(43) Pub. Date: Feb. 13, 2025

(54) SEMICONDUCTOR LIGHT-EMITTING APPARATUS

(71) Applicant: NIKKISO CO., LTD., Tokyo (JP)

(72) Inventors: Izumi KIDA, Hakusan-shi Ishikawa (JP); Naoki SHIBATA, Hakusan-shi Ishikawa (JP); Tetsuhiko INAZU, Hakusan-shi Ishikawa (JP)

(21) Appl. No.: 18/795,517

(22) Filed: Aug. 6, 2024

(30) Foreign Application Priority Data
Aug. 8, 2023 (JP) 2023-129328

(51) Int. Cl. H01L 33/54; H01L 33/48; H01L 33/62

(52) U.S. Cl. CPC H01L 33/54; H01L 33/486; H01L 33/62

(57) ABSTRACT

A semiconductor light-emitting apparatus includes: a package substrate; a semiconductor light-emitting element flip-chip bonded on the package substrate; and a sealing member that covers the semiconductor light-emitting element on the package substrate and has translucency at an emission wavelength of the semiconductor light-emitting element. The semiconductor light-emitting element includes an anode electrode and a cathode electrode bonded to the package substrate, a semiconductor layer on the anode electrode and the cathode electrode, and a translucent substrate on the semiconductor layer. The translucent substrate has an upper surface in contact with the sealing member and a side surface in contact with the sealing member between the upper surface and the semiconductor layer, and an area of the side surface is equal to or less than an area of the upper surface.

### RELATED APPLICATION

Priority is claimed to Japanese Patent Application No. 2023-129328, filed on Aug. 8, 2023, the entire content of which is incorporated herein by reference.

### BACKGROUND

### 1. Technical Field

The present disclosure relates to a semiconductor light-emitting apparatus.

### 2. Description of the Related Art

A semiconductor light-emitting apparatus in which a semiconductor light-emitting element bonded on a package substrate is sealed by a resin is known. For example, a technology for improving light extraction efficiency by forming the sealing resin in an upward convex dome shape has been proposed (see, for example, JP2017-059754A).

To form a sealing member in a dome shape, it is necessary to increase the thickness of the sealing member located above the semiconductor light-emitting element. Increasing the amount of the sealing member filling the dome to increase the thickness of the sealing member increases a distortion caused by a difference in the material between the sealing member and the semiconductor light-emitting apparatus with the result that the sealing member is easily exfoliated or cracked.

### SUMMARY

The present disclosure addresses the issue described above, and a purpose thereof is to provide a technology for improving the optical output and the reliability of a semiconductor light-emitting apparatus.

A semiconductor light-emitting apparatus according to an embodiment of the present disclosure includes: a package substrate; a semiconductor light-emitting element flip-chip bonded on the package substrate; and a sealing member that covers the semiconductor light-emitting element on the package substrate and has translucency at an emission wavelength of the semiconductor light-emitting element. The semiconductor light-emitting element includes an anode electrode and a cathode electrode bonded to the package substrate, a semiconductor layer on the anode electrode and the cathode electrode, and a translucent substrate on the semiconductor layer. The translucent substrate has an upper surface in contact with the sealing member and a side surface in contact with the sealing member between the upper surface and the semiconductor layer, and an area of the side surface is equal to or less than an area of the upper surface.

### BRIEF DESCRIPTION OF THE DRAWINGS

FIG. 1 is a cross sectional view schematically showing a configuration of a semiconductor light-emitting apparatus according to the embodiment.

FIG. 2 is a top view schematically showing a configuration of the semiconductor light-emitting apparatus according to the embodiment.

FIG. 3 is a table showing the optical output and quality of sealing of the semiconductor light-emitting apparatus that result as the thickness of the translucent substrate is changed.

### DETAILED DESCRIPTION

The invention will now be described by reference to the preferred embodiments. This does not intend to limit the scope of the present invention, but to exemplify the invention.

A description will be given of an embodiment to practice the present disclosure with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

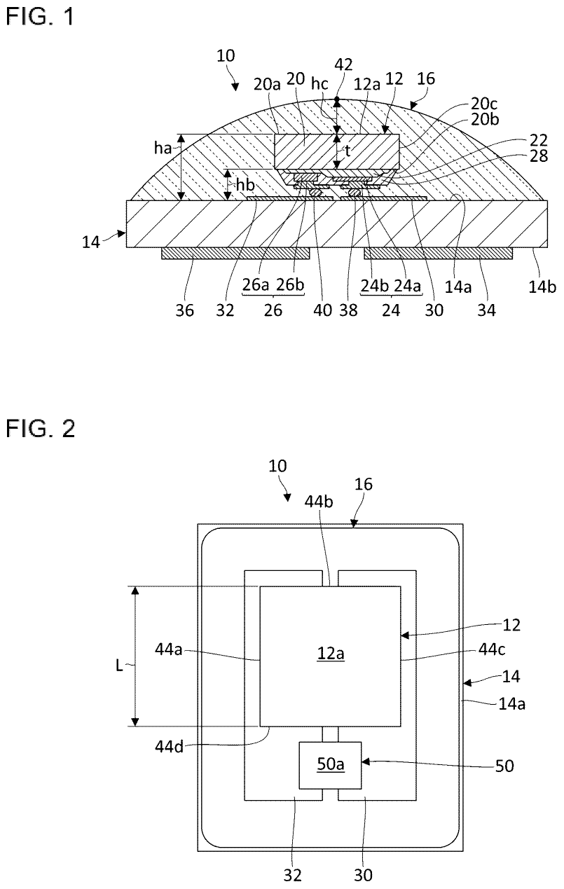

FIG. 1 is a cross sectional view schematically showing a configuration of a semiconductor light-emitting apparatus 10 according to the embodiment. The semiconductor light-emitting apparatus 10 includes a semiconductor light-emitting element 12, a package substrate 14, and a sealing member 16.

The semiconductor light-emitting element 12 is a semiconductor light-emitting element configured to emit ultraviolet light having a central wavelength λ of approximately equal to or less than 360 nm. To output ultraviolet light having such a wavelength, an aluminum gallium nitride (AlGaN)-based semiconductor material having a band gap approximately equal to or more than 3.4 eV is used. In the embodiment, a deep ultraviolet-light emitting diode (DUV-LED) chip configured to emit deep ultraviolet light having a central wavelength λ of about 240 nm-320 nm will be highlighted.

The semiconductor light-emitting element 12 includes a translucent substrate 20, a semiconductor layer 22, an anode electrode 24, a cathode electrode 26, and a protective layer 28.

The translucent substrate 20 is made of a material having translucency for the ultraviolet light emitted by the semiconductor light-emitting element 12. The light emitted by the semiconductor layer 22 is output outside the semiconductor light-emitting element 12 from the translucent substrate 20. The translucent substrate 20 is, for example, made of sapphire (Al₂O₃) or monocrystal aluminum nitride (AlN). The translucent substrate 20 includes an upper surface 20a, a lower surface 20b, and a side surface 20c. The upper surface 20a and the lower surface 20b have, for example, a rectangular shape. The size of the upper surface 20a and the lower surface 20b is not limited to a particular size. For example, the upper surface 20a and the lower surface 20b are 1 mm by 1 mm in size. The thickness t of the translucent substrate 20 from the upper surface 20a to the lower surface 20b is, for example, equal to or more than 50 μm, equal to or more than 100 μm, or equal to or more than 150 μm and is, for example, equal to or less than 300 μm, equal to or less than 250 μm, or equal to or less than 200 μm.

The semiconductor layer 22 is provided below the translucent substrate 20 and is provided on the lower surface 20b of the translucent substrate 20. The semiconductor layer 22 includes, for example, an n-type semiconductor layer, an active layer, and a p-type semiconductor layer. The semiconductor layer 22 is made of an AlGaN-based semiconductor material. The AlGaN-based semiconductor material can be represented by a composition In_{1-x-y}AlₓGa_{y}N (0<x≤y≤1, 0<x<1, 0<y<1). The semiconductor layer 22 is covered by the protective layer 28.

The anode electrode 24 includes a first contact electrode 24a and a first pad electrode 24b. The first contact electrode 24a is an internal electrode in contact with the semiconductor layer 22 and is in contact with the p-type semiconductor layer included in the semiconductor layer 22. The first contact electrode 24a is comprised of, for example, a metal layer made of Rh, etc. The first contact electrode 24a is covered by the protective layer 28. The first pad electrode 24b is an external electrode exposed outside the protective layer 28 and is electrically connected to the first contact electrode 24a via an opening provided in the protective layer 28. The first pad electrode 24b is comprised of a metal layer made of Ni/Au, etc.

The cathode electrode 26 includes a second contact electrode 26a and a second pad electrode 26b. The second contact electrode 26a is an internal electrode in contact with the semiconductor layer 22 and is in contact with the n-type semiconductor layer included in the semiconductor layer 22. The second contact electrode 26a is comprised of, for example, a metal layer made of Ti/Al, etc. The second contact electrode 26a is covered by the protective layer 28. The second pad electrode 26b is an external electrode exposed outside the protective layer 28 and is electrically connected to the second contact electrode 26a via an opening provided in the protective layer 28. The second pad electrode 26b is comprised of a metal layer made of Ni/Au, etc.

The protective layer 28 covers the semiconductor layer 22, the first contact electrode 24a, and the second contact electrode 26a. The protective layer 28 is made of a dielectric material such as oxide and nitride and is made of, for example, silicon oxide (SiO₂), aluminum oxide (Al₂O₃), silicon nitride (SiN), etc. The protective layer 28 may be comprised of a stack of a plurality of protective layers made of different materials.

The package substrate 14 has a flat plate shape and has a bonding surface 14a and a back surface 14b. The package substrate 14 includes a first bonding electrode 30 and a second bonding electrode 32 provided on the bonding surface 14a. The package substrate 14 includes a first mounting electrode 34 and a second mounting electrode 36 provided on the back surface 14b. The first bonding electrode 30 is electrically connected to the first mounting electrode 34 inside the package substrate 14. The second bonding electrode 32 is electrically connected to the second mounting electrode 36 inside the package substrate 14. The package substrate 14 is made of, for example, an inorganic material, and is made of a ceramic material such as alumina (Al₂O₃), aluminum nitride (AlN), silicon nitride (SiN), and silicon carbide (SiC).

The semiconductor light-emitting element 12 is flip-chip bonded on the package substrate 14. The semiconductor light-emitting element 12 is bonded to the first bonding electrode 30 and the second bonding electrode 32. The semiconductor light-emitting element 12 is bonded to the package substrate 14 via a first bonding part 38 and a second bonding part 40. The first bonding part 38 is provided between the anode electrode 24 (the first pad electrode 24b) and the first bonding electrode 30 to connect the anode electrode 24 and the first bonding electrode 30 electrically. The second bonding part 40 is provided between the cathode electrode 26 (the second pad electrode 26b) and the second bonding electrode 32 to connect the cathode electrode 26 and the second bonding electrode 32 electrically.

The first bonding part 38 and the second bonding part 40 are, for example, stud bumps. The first bonding part 38 and the second bonding part 40 are formed by, for example, melting the tip of a metal wire made of Au, etc. to form a ball and pressing the ball against the first bonding electrode 30 and the second bonding electrode 32, respectively. The first bonding part 38 and the second bonding part 40 formed on the first bonding electrode 30 and the second bonding electrode 32 are respectively bonded to the anode electrode 24 (the first pad electrode 24b) and the cathode electrode 26 (the second pad electrode 26b) by, for example, ultrasonic bonding.

In a state where the semiconductor light-emitting element 12 is bonded to the package substrate 14, the height hb from the package substrate 14 (the bonding surface 14a) to the lower surface 20b of the translucent substrate 20 is, for example, smaller than the thickness t of the translucent substrate 20. The height hb from the package substrate 14 to the lower surface 20b of the translucent substrate 20 is, for example, equal to or less than 200 μm, equal to or less than 100 μm, equal to or less than 50 μm, or equal to or less than 30 μm. The height hb from the package substrate 14 to the lower surface 20b of the translucent substrate 20 is, for example, equal to or more than 10 μm, equal to or more than 15 μm, equal to or more than 20 μm, or equal to or more than 25 μm.

In a state where the semiconductor light-emitting element 12 is bonded to the package substrate 14, the height ha from the package substrate 14 (the bonding surface 14a) to the upper surface 12a of the semiconductor light-emitting element 12 (the upper surface 20a of the translucent substrate 20) is, for example, equal to or more than 100 μm, equal to or more than 200 μm, or equal to or more than 250 μm. The height ha from the package substrate 14 to the upper surface 12a of the semiconductor light-emitting element 12 is, for example, equal to or less than 500 μm, equal to or less than 400 μm, or equal to or less than 300 μm.

The sealing member 16 covers the semiconductor light-emitting element 12 on the package substrate 14. The sealing member 16 is formed over the entirety the bonding surface 14a of the package substrate 14. The sealing member 16 is in contact with the bonding surface 14a of the package substrate 14 and is in contact with the first bonding electrode 30 and the second bonding electrode 32. The sealing member 16 is in contact with the side surface 20c and the upper surface 20a of the translucent substrate 20. The sealing member 16 is made of a material having translucency at the emission wavelength of the semiconductor light-emitting element 12. The sealing member 16 has an internal transmittance of equal to or more than 50%, and, preferably equal to or more than 70%, equal to or more than 80%, or equal to or more than 90% at the peak emission wavelength of the semiconductor light-emitting element 12. The sealing member 16 is made of a material having a lower refractive index than the translucent substrate 20. The sealing member 16 is made of, for example, a silicone resin or a fluororesin. The sealing member 16 may be made of an inorganic material such as quartz or may be made of a glass material, instead of a resin. The sealing member 16 is configured not to contain, for example, a phosphor.

The sealing member 16 has, for example, a lens shape or a dome shape that is convex upward. An apex portion 42 of the sealing member 16 is, for example, located above the semiconductor light-emitting element 12 bonded to the package substrate 14. The sealing member 16 is formed to cover the entirety of the upper surface 12a of the semiconductor light-emitting element 12. The height hc from the upper surface 12a of the semiconductor light-emitting element 12 to the apex portion 42 of the sealing member 16 is, for example, equal to or more than 100 μm, equal to or more than 150 μm, or equal to or more than 200 μm. The height hc from the upper surface 12a of the semiconductor light-emitting element 12 to the apex portion 42 of the sealing member 16 is, for example, equal to or less than 500 μm, equal to or less than 400 μm, or equal to or less than 300 μm. The height hc from the upper surface 12a of the semiconductor light-emitting element 12 to the apex portion 42 of the sealing member 16 is, for example, smaller than the height ha of the semiconductor light-emitting element 12. The height hc from the upper surface 12a of the semiconductor light-emitting element 12 to the apex portion 42 of the sealing member 16 is, for example, about the same as the thickness t of the translucent substrate 20. The height hc may be equal to or more than 0.5 times and equal to or less than twice the thickness t of the translucent substrate 20.

FIG. 2 is a top view schematically showing a configuration of the semiconductor light-emitting apparatus 10 according to the embodiment. The semiconductor light-emitting apparatus 10 further includes a protective element 50. The protective element 50 is a diode for protecting the semiconductor light-emitting element 12 from a surge current or static electricity and is, for example, a Zener diode. The protective element 50 is bonded to the bonding surface 14a of the package substrate 14. The protective element 50 is, for example, bonded to the first bonding electrode 30 and the second bonding electrode 32 and is connected in parallel with the semiconductor light-emitting element 12. An upper surface 50a of the protective element 50 is covered by the sealing member 16.

The upper surface 12a of the semiconductor light-emitting element 12 (the upper surface 20a of the translucent substrate 20) has a plurality of sides 44a, 44b, 44c, 44d. In the example of FIG. 2, the upper surface 12a of the semiconductor light-emitting element 12 is rectangular and has four sides 44a-44d. The upper surface 12a of the semiconductor light-emitting element 12 may not be rectangular and may have a polygonal shape such as a triangle, hexagon, or octagon shape different from a quadrilateral shape.

The translucent substrate 20 is preferably configured such that an area Sc of the side surface 20c is equal to or smaller than an area Sa of the upper surface 20a. As shown in FIG. 2, given that the upper surface 20a of the translucent substrate 20 is square, denoting the length of one side 44a as L, and denoting the thickness of the translucent substrate 20 as t, the area Sa of the upper surface 20a is such that Sa=L², and the area Sc of the side surface 20c is such that Sc=4 Lt. In this case, the condition that results in Sa≥Sc is given by L≥4 t. When the length L of one side 44a of the translucent substrate 20 is such that L=1 mm, the thickness t of the translucent substrate 20 is preferably equal to or less than 250 μm. By relatively reducing the area Sc of the side surface 20c of the translucent substrate 20, it is possible to suppress the occurrence of exfoliation and cracks of the sealing member 16 in contact with the side surface 20c.

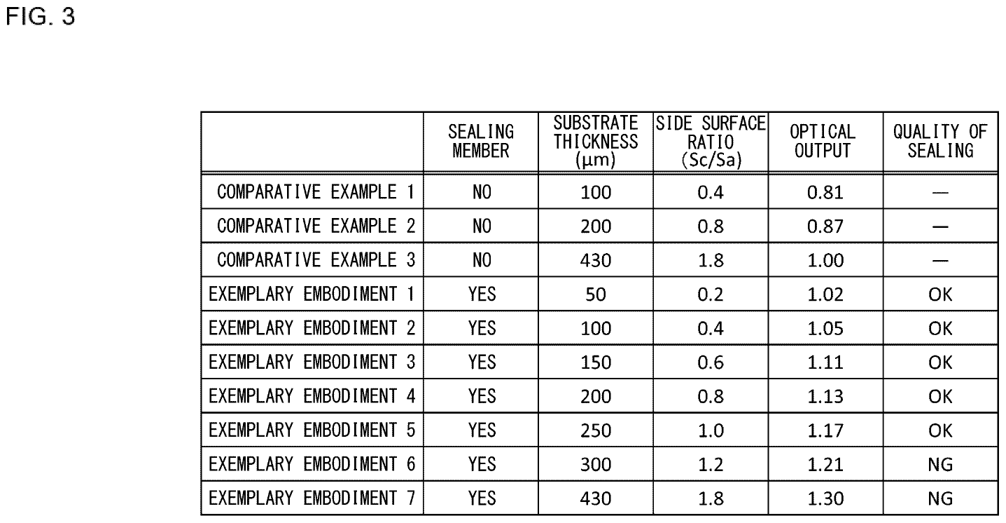

FIG. 3 is a table showing the optical output and quality of sealing of the semiconductor light-emitting apparatus 10 that result as the thickness t of the translucent substrate 20 is changed. In comparative examples 1-3, the sealing member 16 is not provided, and the thickness t of the translucent substrate 20 is set to 100 μm, 200 μm, and 430 μm. In exemplary embodiments 1-7, the sealing member 16 is provided, the thickness t of the translucent substrate 20 is set to 50 μm, 100 μm, 150 μm, 200 μm, 250 μm, 300 μm, 450 μm. The side surface ratio (Sc/Sa) is the area Sc of the side surface 20c with reference to the area Sa of the upper surface 20a of the translucent substrate 20. In the comparative examples and exemplary embodiments, the material of the translucent substrate 20 is sapphire, the material of the sealing member 16 is silicone resin, and the area Sa of the upper surface 20a of the translucent substrate 20 is such that Sa=1 mm² (=1 mm×1 mm).

As shown in FIG. 3, in both the comparative examples and the exemplary embodiments, it will be known that the larger the thickness t of the translucent substrate 20, i.e., the larger the side surface ratio (Sc/Sa), the more improved the optical output. This is considered to be because the amount of ultraviolet light retrieved outside from the translucent substrate 20 increases as the area Sc on the side surface 20c of the translucent substrate 20 increases. In the case of FIG. 3, the sealing member 16 is not provided, and the optical output is normalized by defining the optical output in the comparative example 3, in which of the translucent substrate 20 has a thickness t=430 μm, to be 1.

In the case the sealing member 16 is provided, a larger optical output than in comparative example 3 was obtained in all exemplary embodiments 1-7. From the viewpoint of improving the optical output, the larger the side surface ratio (Sc/Sa), the more preferable. Exemplary embodiments 2-7, in which an improvement in optical output of equal to or more than 5% is seen is preferable. Meanwhile, exfoliation and cracks of the sealing member 16 were observed, and it was found that suitable quality of sealing cannot be obtained in exemplary embodiments 6-7, in which the side surface ratio (Sc/Sa) exceeds 1. Therefore, exemplary embodiments 1-5, in which the side surface ratio (Sc/Sa) is equal to or less than 1, are preferable from the viewpoint of quality of sealing. Based on the foregoing, it is preferable to configure the side surface ratio (Sc/Sa) to be equal to or more than 0.4 and equal to or less than 1.0 and configuring the side surface ratio (Sc/Sa) to be equal to or more than 0.6 and equal to or less than 1.0. The thickness t of the translucent substrate 20 is preferably equal to or more than 100 μm and equal to or less than 250 μm.

According to this embodiment, the semiconductor light-emitting element 12 can be covered and protected, and the optical output of the semiconductor light-emitting apparatus 10 can be improved, by providing the sealing member 16. Further, the occurrence of exfoliation and cracks of the sealing member 16 can be prevented, and the reliability of the semiconductor light-emitting apparatus 10 can be improved by configuring the area Sc of the side surface 20c of the translucent substrate 20 to be equal to or less than the area Sa of the upper surface 20a. As a result, the semiconductor light-emitting apparatus 10 in which both light extraction efficiency and reliability are improved can be provided.

Given above is a description of the present disclosure based on the embodiment. The present disclosure is not restricted by the embodiment described above, and it will be understood by those skilled in the art that various design changes are possible and various modifications are possible and that such modifications are also within the scope of the present disclosure.

Some aspects of the present disclosure will be described.

The first aspect of the present disclosure relates to a semiconductor light-emitting apparatus including: a package substrate; a semiconductor light-emitting element flip-chip bonded on the package substrate; and a sealing member that covers the semiconductor light-emitting element on the package substrate and has translucency at an emission wavelength of the semiconductor light-emitting element, wherein the semiconductor light-emitting element includes an anode electrode and a cathode electrode bonded to the package substrate, a semiconductor layer on the anode electrode and the cathode electrode, and a translucent substrate on the semiconductor layer, wherein the translucent substrate has an upper surface in contact with the sealing member and a side surface in contact with the sealing member between the upper surface and the semiconductor layer, and an area of the side surface is equal to or less than an area of the upper surface. According to the first aspect, the optical output of the semiconductor light-emitting apparatus can be improved by providing the translucent sealing member in contact with the translucent substrate. The occurrence of exfoliation and cracks of the sealing member in contact with the translucent substrate can be prevented, and the reliability of the semiconductor light-emitting apparatus can be improved, by configuring the area of the side surface of the translucent substrate to be equal to or less than the area of the upper surface.

The second aspect of the present disclosure relates to the semiconductor light-emitting apparatus according to the first aspect, wherein the area of the side surface is equal to or more than 0.4 times the area of the upper surface. According to the second aspect, the optical output of the semiconductor light-emitting apparatus can be further improved by configuring the area of the side surface of the translucent substrate to be large.

The third aspect of the present disclosure relates to the semiconductor light-emitting apparatus according to the first or second aspect, wherein a thickness of the sealing member covering the upper surface, in a direction normal to the upper surface, is equal to or more than 0.5 times and equal to or less than twice a thickness t of the translucent substrate. According to the third aspect, the semiconductor light-emitting element can be suitably covered by the sealing member, and the quality of sealing can be improved, by configuring the thickness of the sealing member to be equal to or more than 0.5 times the thickness of the translucent substrate. Further, the occurrence of exfoliation and cracks of the sealing member can be prevented, and the reliability of the semiconductor light-emitting apparatus can be improved, by configuring the thickness of the sealing member to be equal to or less than twice the thickness of the translucent substrate and using an accordingly smaller amount of the sealing member.

The fourth aspect of the present disclosure relates to the semiconductor light-emitting apparatus according to any one of the first to third aspects, wherein the thickness of the sealing member that covers the upper surface, in the direction normal to the upper surface, is equal to or more than 100 μm and equal to or less than 250 μm. According to the fourth aspect, the semiconductor light-emitting element can be suitably sealed by the sealing member, and the occurrence of exfoliation and cracks of the sealing member can be prevented, by configuring the thickness of the sealing member to be equal to or more than 100 μm and equal to or less than 250 μm.

The fifth aspect of the present disclosure relates to the semiconductor light-emitting apparatus according to any one of the first to fourth aspects, wherein the thickness of the translucent substrate is equal to or more than 100 μm and equal to or less than 250 μm. According to the fifth aspect, both the optical output and the reliability of the semiconductor light-emitting apparatus can be improved by configuring the thickness of the translucent substrate to be equal to or more than 100 μm and equal to or less than 250 μm.

The sixth aspect of the present disclosure relates to the semiconductor light-emitting apparatus according to any one of the first to fifth aspects, wherein the translucent member has a dome shape. According to the sixth aspect, the amount of the sealing member covering the semiconductor light-emitting element can be reduced, and the occurrence of exfoliation and cracks of the sealing member can be prevented, by configuring the sealing member to have a dome shape. The efficiency of light extraction through the sealing member can be improved, and the optical output of the semiconductor light-emitting apparatus can be improved by configuring the sealing member to have a dome shape.

What is claimed is:

1. A semiconductor light-emitting apparatus comprising: a package substrate;
a semiconductor light-emitting element flip-chip bonded on the package substrate; and
a sealing member that covers the semiconductor light-emitting element on the package substrate and has translucency at an emission wavelength of the semiconductor light-emitting element,
wherein the semiconductor light-emitting element includes an anode electrode and a cathode electrode bonded to the package substrate, a semiconductor layer on the anode electrode and the cathode electrode, and a translucent substrate on the semiconductor layer,
wherein the translucent substrate has an upper surface in contact with the sealing member and a side surface in contact with the sealing member between the upper surface and the semiconductor layer, and an area of the side surface is equal to or less than an area of the upper surface.

2. The semiconductor light-emitting apparatus according to claim 1,
wherein the area of the side surface is equal to or more than 0.4 times the area of the upper surface.

3. The semiconductor light-emitting apparatus according to claim 1,
wherein a thickness of the sealing member covering the upper surface, in a direction normal to the upper surface, is equal to or more than 0.5 times and equal to or less than twice a thickness t of the translucent substrate.

4. The semiconductor light-emitting apparatus according to claim 3,
wherein the thickness of the sealing member that covers the upper surface, in the direction normal to the upper surface, is equal to or more than 100 μm and equal to or less than 250 μm.

5. The semiconductor light-emitting apparatus according to claim 1,
wherein the thickness of the translucent substrate is equal to or more than 100 μm and equal to or less than 250 μm.

6. The semiconductor light-emitting apparatus according to claim 1,
wherein the translucent member has a dome shape.
